(19) United States
(12) Patent Application Publication
(10) Pub. No.: US 2003/0058629 A1
(43) Pub. Date: Mar. 27, 2003

(54) Wiring substrate for small electronic component and manufacturing method

(76) Inventors: Taro Hirai, Shiga (JP); Gorou Ikegami, Shiga (JP)

Correspondence Address: KATTEN MUCHIN ZAVIS ROSENMAN, 575 MADISON AVENUE, NEW YORK, NY, 10022-2585, US

(21) Appl. No.: 10/253,295

(22) Filed: Sep. 24, 2002

(30) Foreign Application Priority Data
Sep. 25, 2001 (JP) 2001-290695

(51) Int. Cl. H05K 7/10; H05K 7/12

(52) U.S. Cl. 361/767

(57) ABSTRACT

A wiring substrate for used in a small electronic component. The wiring substrate comprises: an insulating substrate; and a conductive land portion which is formed on a first surface of the insulating substrate and on which an electronic element is to be mounted via conductive adhesive to electrically couple an electrode of the electronic element with the conductive land portion. The thickness of the peripheral portion of the conductive land portion which surrounds the electronic element is thicker than that of the central portion of the conductive land portion. The insulating substrate may also have a conductive land portion which is formed on a second surface of the insulating substrate and which is electrically coupled with the conductive land portion formed on the first surface of the insulating substrate via a through hole penetrating through the insulating substrate.

### FIELD OF THE INVENTION

The present invention relates generally to a wiring substrate for a small electronic component, a method of manufacturing the same and an electronic component which uses the wiring substrate.

### BACKGROUND OF THE INVENTION

In a compact, lightweight and portable electronic circuit device, for example, a digital camera, a notebook type personal computer and the like, it is required that electronic components used in such electronic circuit device as well as structural components and mechanical components used in such electronic circuit device are compact and lightweight.

Therefore, in order to downsize the electronic component, an electronic element such as a semiconductor chip and the like used in the electronic component is downsized. In other way, it is also possible to integrate various peripheral circuit blocks into the electronic element to substantially downsize the electronic component, although the size of the electronic element becomes slightly large.

In general, in order to improve productivity, a small electronic component has a lead frame used therein and is encapsulated by using resin. Also, there is a small size electronic component which does not use a lead frame and in which the size of an electronic element is also downsized. In such electronic component, a package structure is improved to further downsize the electronic component.

FIG. 9 is a partially cut away plan view illustrating a workpiece obtained during a manufacturing process of such conventional small size electronic component. The workpiece of FIG. 9 comprises a wiring substrate 1 having a rectangular insulating substrate 2 which is to be divided into a number of areas each corresponding to an electronic component. On both sides of each partitioned area of the insulating substrate 2, there are formed conductive land portions 3 (3a, 3b and 3c) and 4 (4a, 4b and 4c) having predetermined patterns. In the structure shown in FIG. 9, conductive land portions 3 on the surface of the insulating substrate 2 comprises a large size conductive land portion 3a having a rectangular shape and a pair of small size conductive land portions 3b and 3c which are separately disposed in the proximity of the conductive land portion 3a. Also, conductive land portions 4 on the back side of the insulating substrate 2 comprises a large size conductive land portion 4a and small size conductive land portions 4b and 4c which have approximately the same shapes as those of the conductive land portions 3a, 3b and 3c on the surface of the insulating substrate 2, respectively. Although not shown in the drawing, the conductive land portions 3 on the surface of the insulating substrate 2 and the corresponding conductive land portions 4 on the back surface of the insulating substrate 2 are electrically coupled with each other via penetrating holes formed through the insulating substrate 2.

When the insulating substrate 2 is made of a material such as ceramic and the like which can withstand high temperature, the conductive land portions 3 and 4 can be formed by screen-printing conductive paste on the insulating substrate 2 and burning the conductive paste. When the insulating substrate 2 is made of resin, the surfaces of the insulating substrate 2 are roughened. Then, a plating catalyst is then applied onto the roughened surfaces, and plating metal is precipitated by using electroless plating. Further, electroless plating or electroplating is performed on the precipitated metal layer to form a plating layer which has sufficient thickness.

A reference numeral 5 designates an electronic element, for example, a semiconductor pellet. The electronic element 5 has one electrode formed on the backside surface thereof not shown in the drawing, and has two electrodes on the surface side thereof. The backside electrode of the electronic element 5 is mounted on and electrically coupled with the large size conductive land portion 3a via conductive adhesive 6. The electrodes on the surface side of the electronic element 5 are coupled with the small size conductive land portions 3b and 3c via wires 7 and 8, respectively. A reference numeral 9 designates an encapsulation resin portion which coats the insulating substrate 2 and the like such that the electronic component has approximately uniform thickness.

The workpiece of the electronic component shown in FIG. 9 undergoes a cutting process in which the wiring substrate 1 is cut at partitioning line portions (portions shown by dotted lines in FIG. 9), by using a rotary blade not shown in the drawing. Thereby, separate electronic components each shown in FIG. 10 are obtained.

The electronic component of the type mentioned above is disclosed, for example, in Japanese patent laid-open publication No. 11-265964. In such electronic component, since the conductive land portions 3a, 3b and 3c and the conductive land portions 4a, 4b and 4c are disposed close to each other on the insulating substrate, it is possible to downsize and reduce the size of the electronic component, when compared with an electronic component which uses a lead frame. Also, it is possible to manufacture several tens to several hundreds of semiconductor devices at a time from one sheet of insulating substrate 2.

When manufacturing the above-mentioned electronic component, the electronic element 5 is supplied onto the large size conductive land portion 3a generally by using an absorption collet not shown in the drawing.

Also, the conductive adhesive 6 is supplied onto the conductive land portion 3a, by a dispensing method which uses a syringe or by a screen-printing method. In the dispensing method, the quantity of supply of sticky conductive adhesive varies largely. In case the length of a side of an electronic element 5 is 0.5 mm or smaller, when too much conductive adhesive 6 is supplied, the electronic element 5 is buried in the conductive adhesive 6 and there is a possibility that part of the conductive adhesive 6 attaches to the absorption collet.

Further, excess conductive adhesive 6 which is pushed away by the electronic element 5 may attach to the adjacent conductive land portions 3a, 3b and 3c. When such excess conductive adhesive 6 attaches between the conductive land portions for the same electronic component, the conductive land portions are short-circuited and the electronic component becomes a defective product. Also, when such excess conductive adhesive 6 attaches between the conductive land portions of different electronic components, for example, adjacent electronic components, the conductive adhesive 6 is exposed from the encapsulation resin portion 9 as shown in FIG. 11. In such case, the electronic component not only becomes defective from a point of view of an exterior shape or condition, but also causes the following disadvantage. That is, there is a possibility that moisture soaks into the electronic component through an interface between the encapsulation resin portion 9 and the conductive adhesive 6 and deteriorates moisture resistance. Thereby, short circuit may occur between the closely disposed electronic components and the like. Also, there is a possibility that a withstand voltage of the electronic component is deteriorated. Further, in such case, there is a possibility that cutting performance of a rotary blade for cutting the workpiece of the electronic components is deteriorated in a short time.

On the other hand, when the screen printing method is used, the conductive adhesive 6 can be supplied stably with respect to the quantity of supply and the location of supply thereof.

However, in this method, while the conductive adhesive is supplied onto many conductive land portions 3 at the same time, it takes a lot of time for the electronic elements 5 to be supplied onto the respective conductive land portions 3a. The quantity of the conductive adhesive 6 supplied onto each of the conductive land portions 3a is larger than the quantity of the conductive adhesive 6 supplied to each of other conductive land portions 3b and 3c. Therefore, the conductive adhesive 6 supplied onto the conductive land portion 3a flows as time passes and there is a possibility that the conductive adhesive 6 approaches other conductive land portions 3b and 3c or short-circuits the conductive land portion 3a with the closely disposed conductive land portions 3b and 3c.

In order to avoid such disadvantage, it is possible to reduce the supply of the conductive adhesive 6 and to reduce the thickness of the conductive adhesive 6. However, after supplying the conductive adhesive 6, the conductive adhesive 6 dries and cures as time passes, and adhering force of the conductive adhesive 6 is gradually deteriorated. Therefore, the adhering force varies greatly between the electronic element 5 supplied first and the electronic element 5 supplied last.

### SUMMARY OF THE INVENTION

Therefore, it is an object of the present invention to provide a wiring substrate in which conductive adhesive can be easily and quickly supplied onto a conductive land portion and maintained thereon stably, thereby an electronic element can be reliably coupled with the conductive land portion.

It is another object of the present invention to provide a wiring substrate in which a predetermined amount of conductive adhesive can be easily and quickly supplied onto a conductive land portion and maintained thereon stably, thereby the conductive adhesive does not attach to an absorption collet and the like used for supplying an electronic element onto the conductive land portion.

It is still another object of the present invention to provide a wiring substrate in which conductive adhesive supplied onto a conductive land portion does not come out of the conductive land portion, thereby short circuit between the conductive land portions and the like can be surely avoided.

It is still another object of the present invention to provide a wiring substrate in which conductive adhesive supplied onto a conductive land portion does not come out of the conductive land portion and does not expose from an encapsulation resin portion, thereby deterioration of an withstand voltage and the like can be avoided.

It is still another object of the present invention to provide a wiring substrate in which conductive adhesive supplied onto a conductive land portion does not come out of the conductive land portion and does not expose from an encapsulation resin portion, thereby rapid deterioration of a cutting blade can be avoided.

It is still another object of the present invention to provide a method of manufacturing a wiring substrate which attaining the above-mentioned objects of the present invention.

It is still another object of the present invention to provide an electronic component which uses the wiring substrate attaining the above-mentioned objects of the present invention.

It is still another object of the present invention to obviate the disadvantages of the conventional wiring substrate and the electronic component.

According to an aspect of the present invention, there is provided a wiring substrate comprising: an insulating substrate; and a conductive land portion which is formed on a first surface of the insulating substrate and on which an electronic element is to be mounted via conductive adhesive to electrically couple an electrode of the electronic element with the conductive land portion; wherein the thickness of the peripheral portion of the conductive land portion which surrounds the electronic element is thicker than that of the central portion of the conductive land portion.

In this case, it is preferable that the insulating substrate further has a conductive land portion which is formed on a second surface of the insulating substrate and which is electrically coupled with the conductive land portion formed on the first surface of the insulating substrate via a through hole penetrating through the insulating substrate, the second surface being opposite to the first surface.

It is also preferable that the conductive land portion formed on the second surface of the insulating substrate is used for surface mounting an electronic component which is fabricated by using the wiring substrate.

It is further preferable that the insulating substrate has a large size conductive land portion on which the electronic element is to be mounted and at least one small size conductive land portion which is to be electrically coupled with the electronic element via conductive wire or wires.

According to another aspect of the present invention, there is provided a method of manufacturing a wiring substrate comprising: preparing an insulating substrate; applying a photo resist film on the insulating substrate and patterning the photo resist film to form an opening portion to expose a portion of the insulating substrate on which a conductive land portion is to be formed; forming a conductive film on the portion of the insulating substrate which is exposed via the opening portion by using electroless plating; and electro plating the insulating substrate which is electroless plated, in plating solution containing plating additive which improves embedding characteristics, and forming an electro plated conductive film portion on the conductive film portion formed by electroless plating; wherein the thickness of the peripheral portion of the electro plated conductive film portion is thicker than that of the central portion thereof.

According to still another aspect of the present invention, there is provided a method of manufacturing a wiring substrate comprising: preparing an insulating substrate; forming a conductive land area on the insulating substrate; etching the central portion of the conductive land area partially in the thickness direction, thereby, forming a conductive land portion which has a swelled portion on the periphery thereof.

In this case, it is preferable that the forming the conductive land area comprises: forming a thick conductive film on the insulating substrate; applying a photo resist film on the thick conductive film on the insulating substrate and patterning the photo resist film to expose portion or portions of the thick conductive film on the insulating substrate where a conductive land portion is not to be formed; and etching the thick conductive film by using the patterned photo resist film as a mask and forming the conductive land portion on the insulating substrate; and wherein the forming a conductive land portion which has a swelled portion on the periphery thereof comprises: forming a second photo resist film having an opening on the conductive land portion, but the size of the opening is slightly smaller than that of the conductive land portion and the peripheral portion of the conductive land portion is covered by the second photo resist film; and etching the conductive land portion by using the second photo resist film as a mask such that the conductive land portion is partially etched away in the thickness direction.

According to still another aspect of the present invention, there is provided an electronic component comprising: a wiring substrate having an insulating substrate, and a conductive land portion formed on a first surface of the insulating substrate, the thickness of the peripheral portion of the conductive land portion being thicker than that of the central portion of the conductive land portion; and an electronic element mounted on the central portion of the conductive land portion via conductive adhesive to electrically couple an electrode of the electronic element with the conductive land portion.

In this case, it is preferable that the insulating substrate further has a conductive land portion which is formed on a second surface of the insulating substrate and which is electrically coupled with the conductive land portion formed on the first surface of the insulating substrate via a through hole penetrating through the insulating substrate.

It is also preferable that the conductive land portion formed on the second surface of the insulating substrate is used for surface mounting an electronic component which is fabricated by using the wiring substrate.

It is further preferable that the insulating substrate has a large size conductive land portion on which the electronic element is mounted and at least one small size conductive land portion which is electrically coupled with the electronic element via conductive wire or wires.

It is advantageous that the insulating substrate is covered by an encapsulation resin portion on the side the electronic element is mounted.

### BRIEF DESCRIPTION OF THE DRAWINGS

These and other features, and advantages, of the present invention will be more clearly understood from the following detailed description taken in conjunction with the accompanying drawings, in which like reference numerals designate identical or corresponding parts throughout the figures, and in which:

FIG. 1 is a schematic side cross sectional view illustrating an electronic component according to an embodiment of the present invention;

FIG. 2 is a schematic plan view of the electronic component shown in FIG. 1;

FIG. 3 is a schematic side cross sectional view illustrating an insulating substrate used in the electronic component shown in FIGS. 1 and 2;

FIG. 4 is a schematic plan view of the insulating substrate shown in FIG. 3;

FIG. 5 is a schematic cross sectional view showing a workpiece of a wiring substrate during a manufacturing process thereof according to the present invention;

FIG. 6 is a schematic cross sectional view showing a workpiece of a wiring substrate obtained after the structure shown in FIG. 5, during a manufacturing process thereof according to the present invention;

FIG. 7 is a schematic cross sectional view showing a workpiece of a wiring substrate obtained after the structure shown in FIG. 6, during a manufacturing process thereof according to the present invention;

FIG. 8 is a schematic cross sectional view showing a workpiece of a wiring substrate obtained after the structure shown in FIG. 7, during a manufacturing process thereof according to the present invention;

FIG. 9 is a partially cut away plan view illustrating a workpiece obtained during a manufacturing process of a conventional small size electronic component;

FIG. 10 is a cross sectional view illustrating a conventional electronic components obtained from the workpiece shown in FIG. 9; and

FIG. 11 is a cross sectional view illustrating a conventional defective electronic component in which the conductive adhesive is exposed from the encapsulation resin portion.

### DESCRIPTION OF A PREFERRED EMBODIMENT

With reference to the drawings, embodiments of the present invention will now be explained in detail.

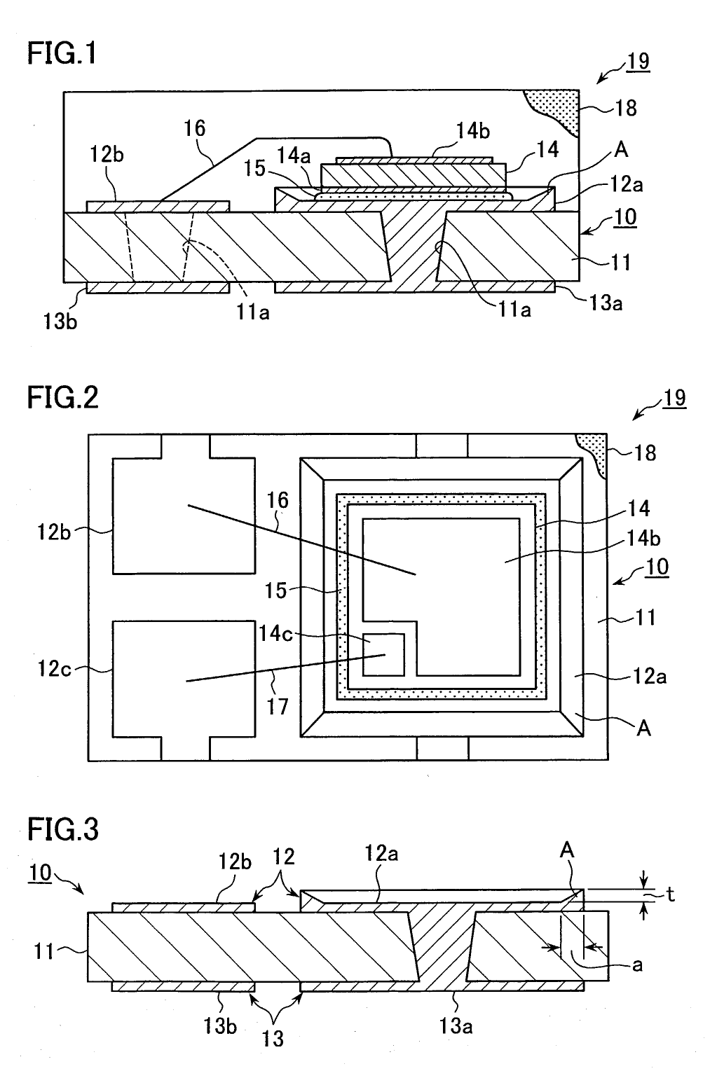

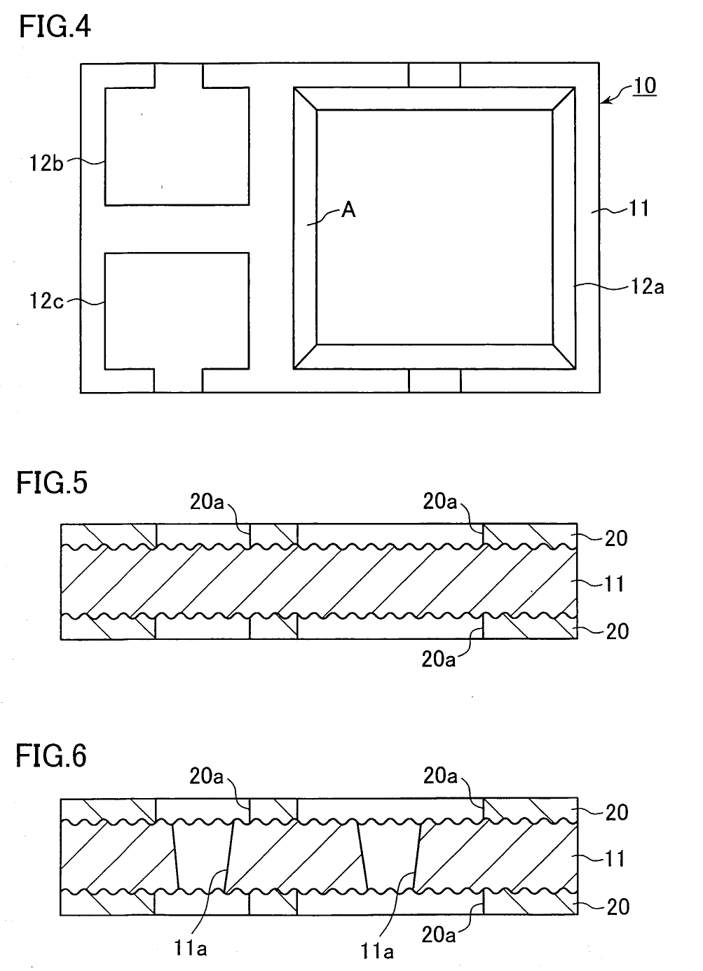

FIG. 1 is a schematic side cross sectional view illustrating an electronic component 19 according to an embodiment of the present invention. FIG. 2 is a schematic plan view of the electronic component 19 shown in FIG. 1. FIG. 3 is a schematic side cross sectional view illustrating an insulating substrate 11 used in the electronic component 19 shown in FIGS. 1 and 2. FIG. 4 is a schematic plan view of the insulating substrate 11 shown in FIG. 3.

As shown in FIG. 1 and FIG. 2, the electronic component 19 generally comprises a wiring substrate 10, an electronic element 14 and an encapsulation resin portion 18.

As also shown in FIG. 3 and FIG. 4, the wiring substrate 10 has an insulating substrate 11 made, for example, of resin. On the surface of the insulating substrate 11, conductive land portions 12 are formed which comprises conductive land portions 12a, 12b and 12c. On the backside surface of the insulating substrate 11, conductive land portions 13 are formed which comprise conductive land portions 13a, 13b and 13c corresponding to the conductive land portions 12a, 12b and 12c, respectively. More particularly, the conductive land portions 12 comprise a large size conductive land portion 12a, and a pair of small size conductive land portions 12b and 12c which are disposed along a side of the conductive land portion 12a and in the proximity of the conductive land portion 12a. Each of the conductive land portions 12a, 12b and 12c has a rectangular shape in this embodiment. Also, in this embodiment, the corresponding conductive land portions 12a and 13a, the conductive land portions 12b and 13b, and conductive land portions 12c and 13c are electrically coupled together via through holes 11a, 11b and 11c which penetrate the insulating substrate 11, respectively.

The conductive land portions 12 and 13 are formed, for example, by plating and have approximately flat profiles. However, at least the large size conductive land portion 12a formed on the surface of the insulating substrate 11 has a profile such that the thickness of the central portion of the conductive land portion 12a on which an electronic element 14 is mounted becomes smaller than the thickness of the peripheral portion thereof. For example, a swelled portion A is formed in the peripheral portion of the conductive land portion 12a, and the swelled portion A has a side cross section which rises from inside toward outside and which has, for example, approximately a right triangle shape.

For example, in the wiring substrate 10 for use in a small size semiconductor device, when the outer size of the wiring substrate 10 is 1.0×1.5×0.25 mm, the thickness of the central portion of the large size conductive land portion 12a is set to be 20-30 μm, and the bottom length “a” of the swelled portion A is approximately 30-100 μm and the height “h” thereof is approximately 5-20 μm.

Referring back to FIG. 1, the electronic element 14 is, for example, a semiconductor pellet such as a transistor, and has large size main electrodes 14a and 14b which are formed on both sides of the semiconductor pellet and through which a main current flows. The electronic element 14 also has a small size control electrode 14c to which a control signal is applied for controlling the flow of the main current. The main electrode 14a is formed on the bottom surface of the electronic element 14, and the main electrode 14b and the control electrode 14c are formed on the upper surface of the electronic element 14. The electronic element 14 is mounted on the large size conductive land portion 12a. That is, the large size main electrode 14a on the bottom of the electronic element 14 is electrically and mechanically coupled with the large size conductive land portion 12a via conductive adhesive 15 such as silver paste and the like. Also, the main electrode 14b and the control electrode 14c on the top of the electronic element 14 are electrically coupled with the small size conductive land portions 12b and 12c via wires 16 and 17, respectively. The encapsulation resin portion 18 covers and encapsulates the top surface of the wiring substrate 10 including the electronic element 14 and the like.

It is possible to make the thickness in the external size of the electronic component 19 equal to or smaller than 0.5 mm. Therefore, the electronic component 19 is suitable for use as a surface mountable small size electronic component. When the thickness of the electronic component 19 is smaller than, for example, 1.0 mm, it is also necessary to reduce the size of the conductive land portion 12 on the wiring substrate 10. The electronic component 19 according to the present invention has the swelled portion A which has a height of approximately 5-20 μm in the periphery of the large size conductive land portion 12a. Therefore, it is possible to form a retaining space between the swelled portion A and the electronic element 14, and to hold the conductive adhesive 15 in this space. Thus, it becomes possible to avoid the conductive adhesive 15 from approaching and/or reaching other conductive land portions 12b, 12c and the like on the insulating substrate 11.

As a practical example, assume the large size conductive land portion 12a has a square shape and the length of a side thereof is 750 μm, the bottom side length “a” of the swelled portion “A” is 50 μm and the height “h” is 10 μm. In such case, the volume of a flat portion surrounded by the swelled portion “A” is approximately 4.2×10⁶ μm³, and the volume of the swelled portion “A” is approximately 7×10⁵ μm³. Therefore, the volume of the swelled portion “A” becomes ⅙ (approximately 16%) of the volume of a flat portion surrounded by the swelled portion “A”. When mounting the electronic element 14 onto the conductive land portion 12a, the conductive adhesive 15 supplied onto the conductive land portion 12a is pressed by the electronic element 14 and some of the conductive adhesive 15 is pushed away from the bottom portion of the electronic element 14. However, the conductive adhesive 15 pushed away from the bottom portion of the electronic element 14 can be retained on the conductive land portion 12a by the swelled portion A.

Even if the conductive adhesive 15 pushed away from the bottom portion of the electronic element 14 gets over the swelled portion A, the quantity of the conductive adhesive 6 getting over the swelled portion A can be small. Therefore, it is possible to prevent the conductive adhesive 15 from approaching the adjacent conductive land portions 12b, 12c and the like, and to avoid the disadvantages of short circuit, deterioration of withstand voltage and the like. Also, it is possible to prevent the conductive adhesive 15 from exposing from the encapsulation resin portion 18 and to avoid short circuit of the electronic component 19 with other electronic component(s) disposed adjacently to the electronic component 19.

An explanation will now be made on a method of manufacturing a wiring substrate used for fabricating an electronic component according to the present invention.

First, as shown in FIG. 5, an insulating substrate 11 is prepared which is made, for example, of resin and in which both surfaces thereof are roughened. Then, photo sensitive resist films or photo resist films 20 are applied onto both sides of the insulating substrate 11. The photo resist films 20 are patterned into predetermined patterns by using a photolithography technology, thereby the insulating substrate 11 is exposed at predetermined opening portions 20a.

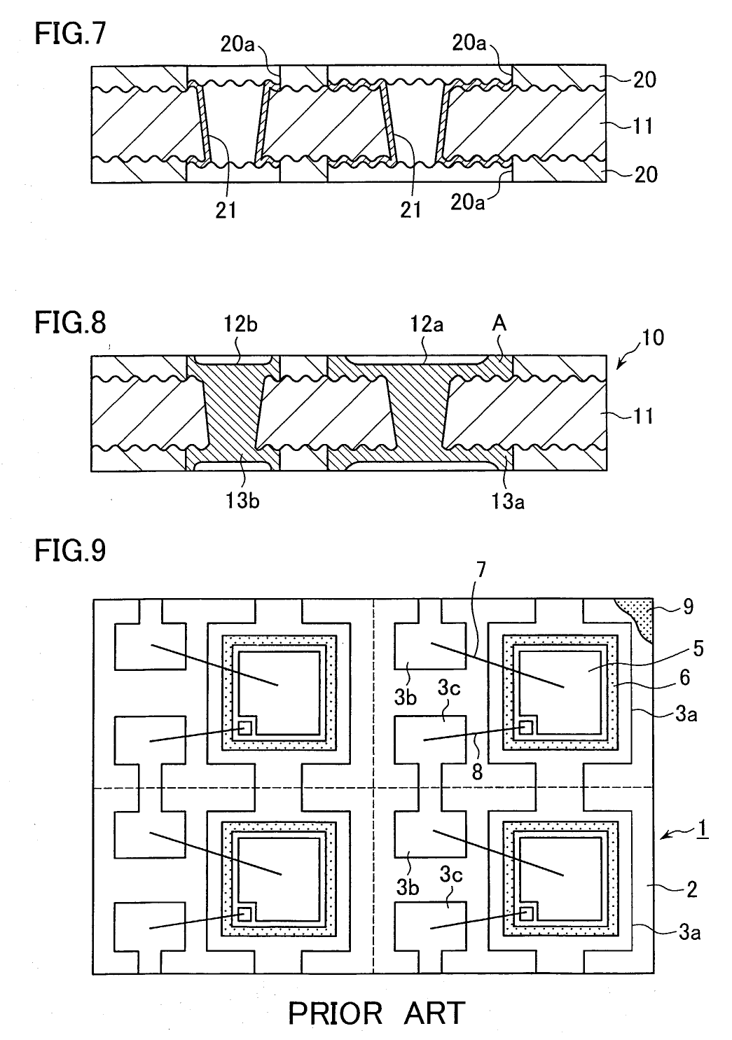

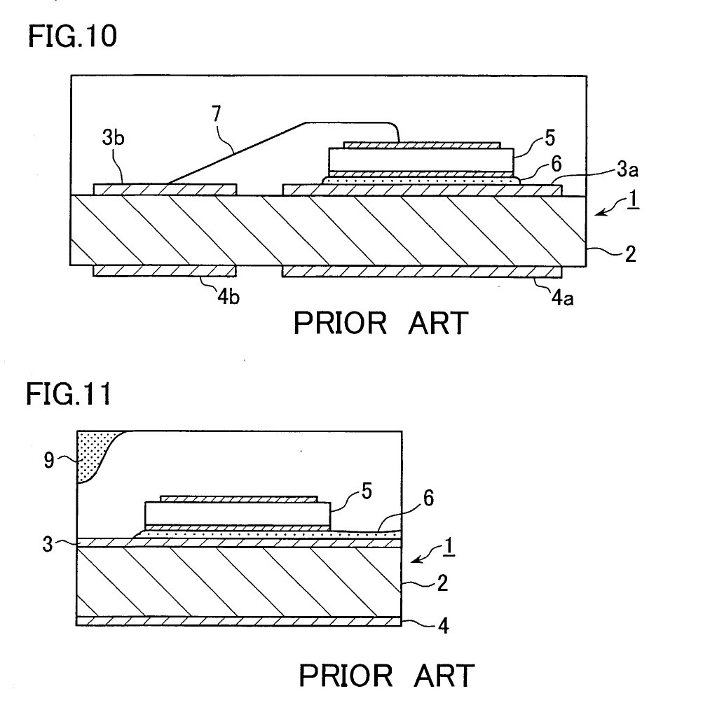

As shown in FIG. 6, in the opening portions 20a where the insulating substrate 11 is exposed, penetrating holes 11a are formed which penetrate the insulating substrate 11. Although not shown in the drawing, the insulating substrate 11 is then soaked in liquid plating catalyst, and plating catalyst is applied to the opening portions 20a and the through holes 11a of the insulating substrate 11. Further, such insulating substrate 11 is soaked in electroless plating solution, and as shown in FIG. 7, a plated layer 21 is formed which coats an inner wall of each of the through holes 11a and the opening portions 20a.

Thereby, portions of the plated layer 21 on both sides of the insulating substrate 11 are electrically coupled with each other via a portion of the plated layer 21 which coats the inner wall of the through hole 11a. Thereafter, the insulating substrate 11 is soaked in electroplating solution, and electroplating is performed on the electroless plated layers 21. By adding plating additive of leveler type copper sulfate to electroplating solution having copper sulfate as main ingredient, it is possible to fill the through hole 11a with plating material and cover the portions of the plated layer 21 with an electroplated layer to increase the thickness thereof. The additive improves embedding characteristics of a blind via hole and the like. The plating solution is obtained by mixing 160-240 g/L of copper sulfate, 40-80 g/L of sulfuric acid, 30-70 mg/L of chlorine ions, 2-10 mL/L of additive (OKUNO CHEMICAL INDUSTRIE CO., LTD./product name “TOP LUCINA BVF”). The plating is performed on condition that bath temperature is 18-30° C. and cathode current density is 1-5 A/dm².

By using the plating condition mentioned above, the through holes 11a are filled with the plating material. Also, the plated layers 21 are covered by the plating material and become thick. In this case, as shown in FIG. 8, in each of the opening portions 20a, the plating material of a peripheral portion thereof becomes thicker than that of a central portion thereof. Therefore, when the photo resist films 20 are removed, it is possible to obtain a wiring substrate 10 having the conductive land portions 12 in each of which the thickness of the peripheral portion is thicker than that of the central portion. In this way, by only adding the additive to the plating solution to fill the through holes 11a, it is possible to form conductive land portions 12 in which the thickness of the peripheral portion is thicker than that of the central portion, and to use the insulating substrate having such conductive land portions as a wiring substrate for use in a small size electronic component.

In the above-mentioned method of manufacturing the wiring substrate 10, the plating layers 21 are formed on both sides of the insulating substrate 11 and these plating layers 21 are electrically coupled with each other by using the plating material which fills the through holes 11a. However, it is also possible to form the plating layer 21 only on one side of the insulating substrate 11. In such case, it is not necessary to form through holes like the through holes 11a.

The present invention is not limited to the structure and method mentioned above. For example, the wiring substrate according to the present invention can be fabricated in another way. That is, an insulating substrate on which sufficiently thick conductive layers are formed is coated by photo resist films. The photo resist film is patterned such that predetermined portions are removed. The removed portions of the photo resist film are etched away, and thereby conductive land portions having predetermined patterns are formed. Then, another photo resist film is formed and patterned such that the photo resist film has openings on the conductive land portions. The size of each of the openings is slightly smaller than that of the corresponding conductive land portion and the peripheral portion of the conductive land portion is covered by the photo resist film. By using such photo resist film as a mask, the conductive land portions are etched away such that the central portions thereof become thinner than the peripheral portions. Thereby, it is possible to form conductive land portions which have swelled portions on the periphery thereof.

As mentioned above, in the wiring substrate according to the present invention, a thickness of the peripheral portion of the conductive land portion on which the electronic element is mounted is made thicker than that of the central portion thereof. Therefore, it becomes possible to prevent the sticky conductive adhesive from flowing out of the conductive land portion and to retain a predetermined amount of conductive adhesive stably on each of the conductive land portions even when the conductive adhesive is supplied onto many conductive land portions simultaneously by using a screen-printing method and the like.

It is also possible to prevent the conductive adhesive from attaching to an absorption collet used for supplying an electronic element onto the conductive land portion.

Further, it is possible to prevent excess conductive adhesive from reaching the adjacent conductive land portion and exposing from an encapsulation resin portion. Thereby, short circuit between the conductive land portions, deterioration of an withstand voltage and the like can be surely avoided.

Also, when the encapsulation resin portion is cut by using a cutting blade, it is possible to avoid rapid deterioration of the cutting blade.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative sense rather than a restrictive sense, and all such modifications are to be included within the scope of the present invention. Therefore, it is intended that this invention encompasses all of the variations and modifications as falling within the scope of the appended claims.

What is claimed is:

1. A wiring substrate comprising:
an insulating substrate; and
a conductive land portion which is formed on a first surface of the insulating substrate and on which an electronic element is to be mounted via conductive adhesive to electrically couple an electrode of the electronic element with the conductive land portion;
wherein the thickness of the peripheral portion of the conductive land portion which surrounds the electronic element is thicker than that of the central portion of the conductive land portion.

2. A wiring substrate as set forth in claim 1, wherein the insulating substrate further has a conductive land portion which is formed on a second surface of the insulating substrate and which is electrically coupled with the conductive land portion formed on the first surface of the insulating substrate via a through hole penetrating through the insulating substrate, the second surface being opposite to the first surface.

3. A wiring substrate as set forth in claim 2, wherein the conductive land portion formed on the second surface of the insulating substrate is used for surface mounting an electronic component which is fabricated by using the wiring substrate.

4. A wiring substrate as set forth in claim 1, wherein the insulating substrate has a large size conductive land portion on which the electronic element is to be mounted and at least one small size conductive land portion which is to be electrically coupled with the electronic element via conductive wire or wires.

5. A method of manufacturing a wiring substrate comprising:
preparing an insulating substrate;
applying a photo resist film on the insulating substrate and patterning the photo resist film to form an opening portion to expose a portion of the insulating substrate on which a conductive land portion is to be formed;
forming a conductive film on the portion of the insulating substrate which is exposed via the opening portion by using electroless plating; and
electro plating the insulating substrate which is electroless plated, in plating solution containing plating additive which improves embedding characteristics, and forming an electro plated conductive film portion on the conductive film portion formed by electroless plating;
wherein the thickness of the peripheral portion of the electro plated conductive film portion is thicker than that of the central portion thereof.

6. A method of manufacturing a wiring substrate comprising:
preparing an insulating substrate;
forming a conductive land area on the insulating substrate;
etching the central portion of the conductive land area partially in the thickness direction, thereby, forming a conductive land portion which has a swelled portion on the periphery thereof.

7. A method of manufacturing a wiring substrate as set forth in claim 6, wherein the forming the conductive land area comprises:
forming a thick conductive film on the insulating substrate;
applying a photo resist film on the thick conductive film on the insulating substrate and patterning the photo resist film to expose portion or portions of the thick conductive film on the insulating substrate where a conductive land portion is not to be formed; and
etching the thick conductive film by using the patterned photo resist film as a mask and forming the conductive land portion on the insulating substrate; and
wherein the forming a conductive land portion which has a swelled portion on the periphery thereof comprises:
forming a second photo resist film having an opening on the conductive land portion, but the size of the opening is slightly smaller than that of the conductive land portion and the peripheral portion of the conductive land portion is covered by the second photo resist film; and
etching the conductive land portion by using the second photo resist film as a mask such that the conductive land portion is partially etched away in the thickness direction.

8. An electronic component comprising:
a wiring substrate having an insulating substrate, and a conductive land portion formed on a first surface of the insulating substrate, the thickness of the peripheral portion of the conductive land portion being thicker than that of the central portion of the conductive land portion; and
an electronic element mounted on the central portion of the conductive land portion via conductive adhesive to electrically couple an electrode of the electronic element with the conductive land portion.

9. An electronic component as set forth in claim 8, wherein the insulating substrate further has a conductive land portion which is formed on a second surface of the insulating substrate and which is electrically coupled with the conductive land portion formed on the first surface of the insulating substrate via a through hole penetrating through the insulating substrate, the second surface being opposite to the first surface.

10. An electronic component as set forth in claim 9, wherein the conductive land portion formed on the second surface of the insulating substrate is used for surface mounting an electronic component which is fabricated by using the wiring substrate.

11. An electronic component as set forth in claim 8, wherein the insulating substrate has a large size conductive land portion on which the electronic element is mounted and at least one small size conductive land portion which is electrically coupled with the electronic element via conductive wire or wires.

12. An electronic component as set forth in claim 8, wherein the insulating substrate is covered by an encapsulation resin portion on the side the electronic element is mounted.
